(19) United States
(12) Patent Application Publication
(10) Pub. No.: US 2013/0069660 A1
(43) Pub. Date: Mar. 21, 2013

(54) METHOD FOR IN SITU BATTERY DIAGNOSTIC BY ELECTROCHEMICAL IMPEDANCE SPECTROSCOPY

(71) Applicants: Julien Bernard, Oullins (FR); Arnaud Delaille, Bassens (FR); François Huet, Breuillet (FR); Jean-Marie Klein, Communay (FR); Rémy Mingant, Vienne (FR); Valérie Sauvant-Moynot, Lyon (FR)

(72) Inventors: Julien Bernard, Oullins (FR); Arnaud Delaille, Bassens (FR); François Huet, Breuillet (FR); Jean-Marie Klein, Communay (FR); Rémy Mingant, Vienne (FR); Valérie Sauvant-Moynot, Lyon (FR)

(21) Appl. No.: 13/579,357

(22) PCT Filed: Feb. 11, 2010
(86) PCT No.: PCT/FR2011/000083

§ 371 Date: Nov. 28, 2012

(30) Foreign Application Priority Data
Feb. 17, 2010 (FR) 1000665

(51) Int. Cl. G01R 31/36; G01N 27/416

(52) U.S. Cl. 324/430

(57) ABSTRACT

The invention is a method for estimating the internal state of a system for the electrochemical storage of electrical energy, such as a battery. For various internal states of batteries of the same type as a battery being analysed, impedance measurements are carried out by adding an electrical signal to the current passing through the batteries. Then, an RC circuit is used to model the impedances. Next, a relationship is calibrated between the SoC (and/or the SoH) and the parameters of the RC circuit using multivariate statistical analysis. A measurement of the impedance of the battery under analysis is carried out which is modeled using the RC circuit. Finally, the relationship of the equivalent electric circuit defined for the battery being analysed is used to estimate the internal state of that battery.

### CROSS REFERENCE TO RELATED APPLICATION

Reference is made to French Patent Application Serial No. 10/00.665, filed on Feb. 17, 2010, which application is incorporated herein by reference in its entirety.

### BACKGROUND OF THE INVENTION

1. Field of the Invention

The present invention relates to a method for estimating an internal state of an electrochemical system for the storage of electrical energy, such as a battery (lead, Ni-MH, Li-ion, etc.) which can be used to manage batteries used in stationary or on-board applications, in particular while they are in operation.

2. Description of the Prior Art

The battery is one of the most critical components in the case of hybrid or electric vehicle applications or for the storage of photovoltaic solar energy. Proper operation of those applications relies upon a battery management system (BMS) which is concerned with having the battery operating with the best compromise between the various dynamic loading levels. That BMS requires a precise, reliable knowledge of the state of charge (SoC) and of the state of health (SoH).

The state of charge of a battery (SoC) corresponds to its available capacity and is expressed as the percentage of its nominal capacity indicated by the manufacturer or as the percentage of its total capacity measured under given conditions when that measurement is possible. Knowing the SoC means that the time during which the battery can continue to supply energy at a given current before its next recharge, or until when it can absorb energy before its next discharge, can be estimated. This information conditions the operation of systems using batteries.

During the life of a battery, its performance tends to degrade gradually due to physical and chemical variations that occur during use, until it is no longer usable. The state of health (SoH) represents the state of wear of a battery. This parameter corresponds to the total capacity of a battery at a time t during its service life and is expressed as a percentage of the total capacity determined at the start of its service life, equivalent to the nominal capacity indicated by the manufacturer, or the capacity measured at the start of its service life under given conditions.

A precise and reliable estimate of the SoC and of the SoH for a vehicle means, for example, that the driver of the vehicle will not have to be overly prudent in using the potential for energy of the battery, or vice versa. A poor diagnostic of the state of charge may result in an overestimation of the number of kilometres that can be driven, thereby causing problems for a driver. A good estimate of these indicators also means that batteries would not need to be oversized for safety reasons, thereby saving on-board weight and as a consequence, saving on fuel consumption. Estimation of the SoC and SoH can also reduce the total cost of the vehicle. An accurate estimator thus constitutes a guarantee of efficient and safe use of the capacity of the battery over the whole range of operations of the vehicle.

A number of methods are known for estimating the state of charge (SoC) and the state of health (SoH) of a battery.

Examples of known methods are “coulomb-counting” or “book-keeping” methods. However, such methods result in errors in estimation as they ignore phenomena, such as self-discharge. A method is also known in which the open circuit voltage is measured as an indicator of the SoC. The use of other indicators is known, such as, for example, an estimation of an internal resistance is disclosed in U.S. Pat. No. 6,191,590 B1 and European Patent 1 835 297 A1).

With these two methods, SoC is associated with one or more measurable or easily estimated quantities (potential, internal resistance) with static charts or analytical functional dependencies. However, in reality, such dependencies are much more complicated than what is normally taken into account in the BMS, which often leads to errors in estimating the SoC.

A potentially more promising method is based on measuring a quantity governed by the SoC using impedance spectroscopy (EIS). As an example, U.S. Published Application 2007/0090843 discloses determining, by EIS, the frequency f± associated with the capacitive/inductive transition. A correlation between the frequency f± and the SoC is presented for a lead battery as well as for Ni—Cd and Ni-MH batteries. A similar approach is based on modeling the EIS spectra by equivalent electrical circuits where components are governed by the SoC, as described in U.S. Pat. No. 6,778,913 B2, which led to the development of an automobile battery tester, the Spectro CA-12 (Cadex Electronics Inc, Canada) based on multi-frequency electrochemical impedance spectroscopy for the acid-lead pairing. The EIS spectra are approached by equivalent electrical circuits and change in the components is governed by the SoC. Similarly, in U.S. Pat. No. 6,037,777, the state of charge and other properties of the batteries are determined by measuring the real and imaginary parts of the complex impedance/admittance for lead batteries or other systems. The use of RC models is also described in EP 0 880 710 in which the description of the electrochemical and physical phenomena at the electrodes and in the electrolyte serves as a support for the development of the RC model. The temperature of the battery is simulated by the model in order to increase precision with respect to an external measurement.

An alternative approach is based on battery mathematical models, for using estimation techniques that are known from other fields. U.S. Published Application 2007/0035307 A1 in particular describes a method for estimating state variables and the parameters of a battery from operating data (voltage U, current I, T) using a battery mathematical model. The mathematical model comprises a plurality of mathematical sub-models which provide a more rapid response. The sub-models are equivalent electrical circuit type models associated with restricted frequency ranges. These models are identified as RC models.

Another method for estimating the SoC which is known from the literature ([Gu, White, etc.]) is based on a mathematical description of the reactions of an electrochemical system. The SoC is calculated from state variables for the system. That description is based on material, charge, energy, etc. balances as well as on semi-empirical correlations.

Regarding methods for estimating SoH which are known in the literature, the authors of document WO 2009/036444 introduce a reference electrode into commercial elements in order to observe electrode degradation reactions. However, that method demands a great deal of instrumentation, in particular for insertion of a reference electrode into the element, as well as more complex electronic management of the battery.

French Patent 2 874 701 describes a method using a temporal electrical perturbation for comparing the response obtained with a reference response. However, that method is more difficult to implement for elements of the Li-ion type which exhibit very weak variations in response to that type of perturbation and thus do not provide a precise measurement of SoH.

Impedance analyses have also been described in the literature. U Tröltzsch et al (Electrochimica Acta 51, 2006, 1664-1672) describe a method in which impedance spectroscopy coupled with adjustment of the impedances in accordance with an electrical model is used to obtain the SoH. That technique, however, requires stopping using the element to make the measurement.

### SUMMARY OF THE INVENTION

Thus, the invention provides an alternative method for estimating an internal state of an electrochemical system for the storage of electrical energy, such as a battery. The method is based on a measurement of the impedance of the system in order to reconstruct its internal state by a predetermined statistical model as a function of a model of the battery and of its application. In particular, the method can be used to estimate the state of charge (SoC) and the state of health (SoH) of an electrochemical battery which are the most important internal characteristics for the majority of applications using batteries, whether they be stationary or on-board.

The method of the invention estimates an internal state of a first electrochemical system for the storage of electrical energy, such as a battery, in which at least one property relating to the internal state of the first electrochemical system is estimated from an electrical measurement obtained by impedance spectroscopy. The method comprises the following steps:
for various internal states of at least one second electrochemical system of the same type as the first electrochemical system measuring the at least one property relating to the internal state of the second system and carrying out an electrical measurement of the second electrochemical system at various frequencies using impedance spectroscopy;
defining an equivalent electrical circuit comprising at least one parameter for modeling the electrical responses of the second system;
calibrating a relationship between the at least one property and the at least one parameter of the equivalent electrical circuit using a statistical analysis of values the at least one property and for the at least one parameter obtained for the internal states;
determining an electrical response of the first electrochemical system for frequencies which is modeled using the equivalent electrical circuit by determining the at least one parameter such that an electrical response of the equivalent electrical circuit is equivalent to the electrical response of the first electrochemical system; and
estimating the internal state of the first electrochemical system by calculating the property relating to the internal state of the electrochemical system using the relationship.

According to the invention, various internal states may be obtained by carrying out accelerated aging of a second electrochemical system for the storage of electrical energy of the same type as the first electrochemical system. The various internal states may also be obtained by selecting a set of second electrochemical systems of the same type as the first electrochemical system with the systems of the set having different internal states.

It is possible to calculate at least one of the following properties relating to the internal state of the electrochemical system: a state of charge (SoC) of the system and a state of health (SoH) of the system.

The equivalent electrical circuit may be defined by a plurality of parameters selected from the following parameters: resistance, capacity, temperature or any combination of the parameters.

According to the invention, it is possible to determine an electrical response for different frequencies by measuring the electrical impedance diagrams obtained by adding an electrical signal to a current passing through the electrochemical system. These electrical impedance diagrams may be measured by applying a sinusoidal current perturbation to the electrochemical system, and by measuring a sinusoidal voltage induced at the terminals of the electrochemical system. These electrical impedance diagrams may also be measured by applying a perturbation which is a superposition of a plurality of sinusoidal curves or white noise applied to the electrochemical system and in response to measuring a sinusoidal voltage induced at the terminals of the electrochemical system.

According to the invention, the electrochemical system may be at rest (vehicle stopped or stationary), or in operation.

The invention also concerns a system for estimating an internal state of an electrochemical system for the storage of electrical energy, comprising:
a sensor (G) including means for measuring the electrical impedance of the electrochemical system by impedance spectroscopy;
a memory for storing an equivalent electrical circuit and a relationship between a property relating to an internal state of the electrochemical system and the parameters of the equivalent electrical circuit, the relationship being calibrated by measurements of internal states of at least one second electrochemical system of a same type as the electrochemical system;
means for defining parameters of equivalent electrical circuit modeling an electrical response of the electrochemical system; and
means for calculating a property relating to the internal state of the electrochemical system using the relationship.

According to the invention, the means for measuring the electrical impedance comprises:
a galvanostat for applying a sinusoidal current perturbation or a perturbation comprising a superposition of a plurality of sinusoidal curves or white noise to the electrochemical system; and
means for measuring a sinusoidal voltage induced at terminals of the electrochemical system.

The invention is also a battery management system comprising a system for estimating an internal state of a battery in accordance with the invention.

The invention is also a vehicle comprising a battery and a battery management system in accordance with the invention.

The invention also concerns a photovoltaic system for storing electrical energy, comprising a system for estimating its internal state in accordance with the invention.

Further characteristics and advantages of the method of the invention will become apparent from the following description of non-limiting examples of embodiments made with reference to the accompanying figures which are described below.

### BRIEF DESCRIPTION OF THE INVENTION

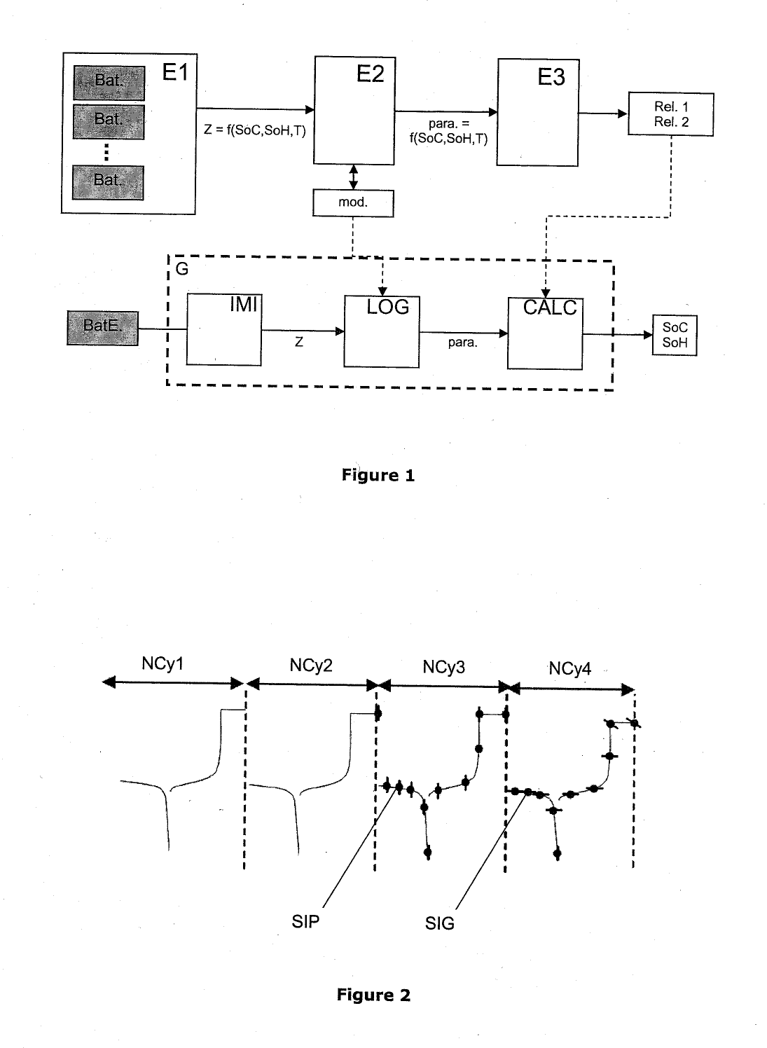

FIG. 1 is the logic diagram of the method of the invention;

FIG. 2 illustrates a check-up procedure with impedance measurements;

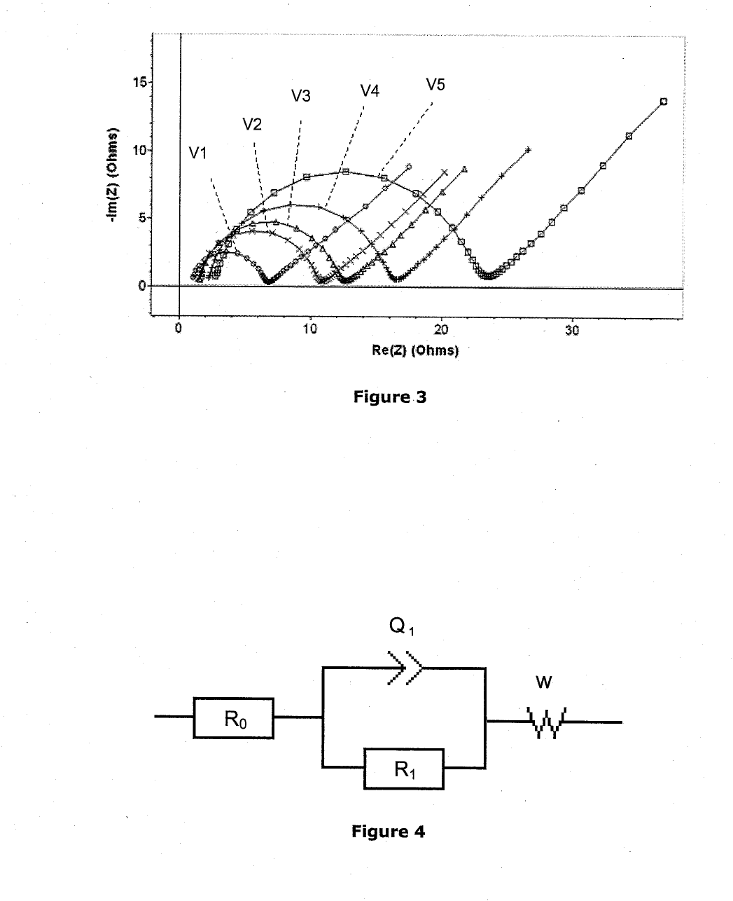

FIG. 3 shows a comparison between impedances obtained for states of aging representative of a VEH application at a state of charge of 20% for a Li₄Ti₅O₁₂/LiFePO₄ type battery;

FIG. 4 illustrates an example of an equivalent electrical circuit representative of an electrochemical accumulator;

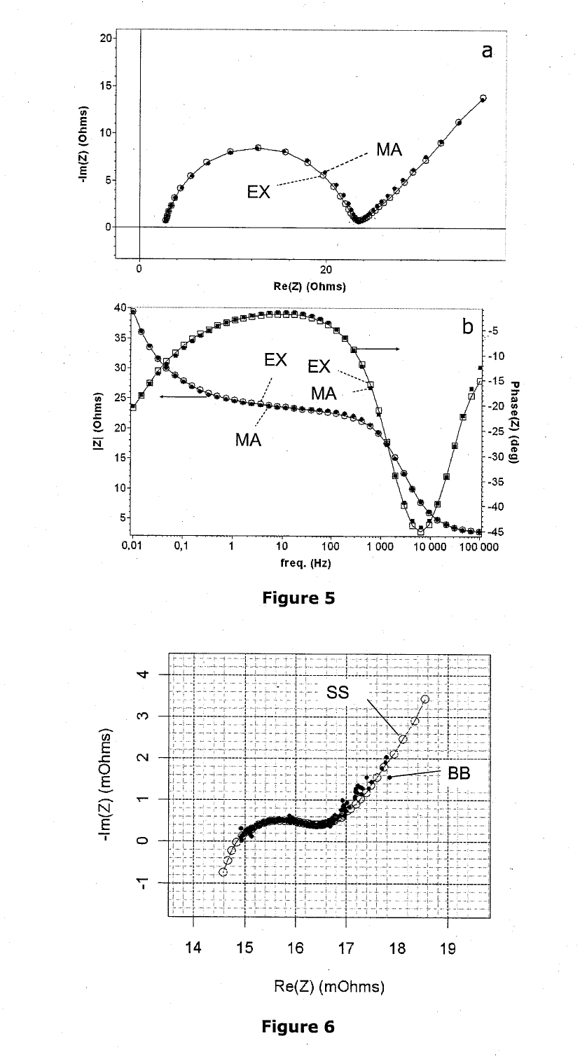

FIG. 5 shows an example of an adjustment for the model for impedance between 65 kHz and 0.1 Hz for a Li₄Ti₅O₁₂/LiFePO₄ battery at 20% SoC in a Nyquist representation a), and in a Bode representation b), and using the equivalent circuit model of FIG. 4;

FIG. 6 illustrates a comparison between an impedance obtained by imposing sinusoidal signals (SS) and an impedance obtained with white noise (BB);

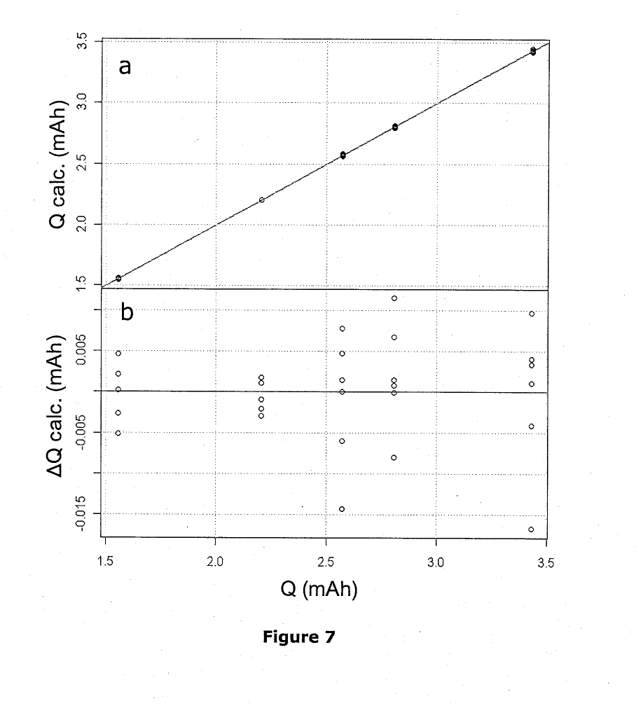

FIG. 7 illustrates the straight line calculated for the capacity of the battery based on the relationship for estimating the SoH against the measured capacity for the battery a) and residuals b) representing the difference between the capacity calculated from the impedance diagrams and the measured capacity of the battery;

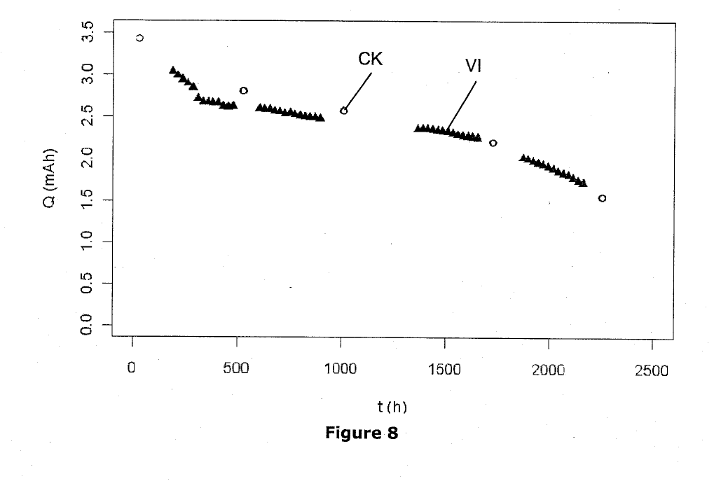

FIG. 8 illustrates a measurement of the capacity of a battery by a complete cycle during check-ups at 20° C. (CK) and by impedance at 50° C. during aging (VI); and

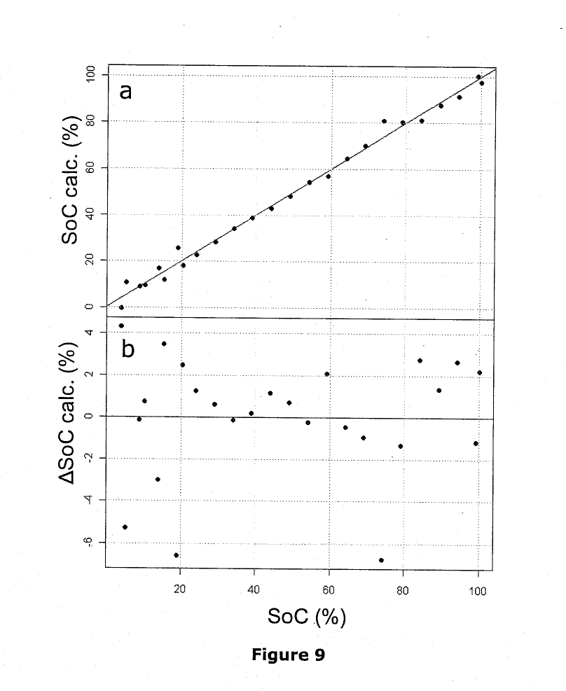

FIG. 9 illustrates the straight line calculated for the SoC of the battery based on the relationship for estimating the SoC against measured values for SoC a), and residuals b), representing the difference between the SoC calculated from impedance diagrams and the measured SoC.

### DETAILED DESCRIPTION OF THE INVENTION

The invention can be used to gauge the state of charge or state of health of a battery with a pre-identified model and technology for its use in a transport application (traction battery) or for storing renewable energy. The invention consolidates estimates of SoC and SoH made by the BMS with data not being directly measurable.

The method is potentially on-board in a vehicle or used when storing energy in the context of photovoltaic solar systems connected to a grid and can be used to quantitatively determine the state of charge (SoC) and the state of health (SoH) of batteries, in particular Li-ion batteries, based on a measurement of the electrical impedance at the terminals of the electrodes of the system with the measurement being non-intrusive and at a controlled temperature.

The logic diagram of the method is shown in FIG. 1. The method of the invention comprises the following steps:

Step E1 carries out a program of laboratory tests on a batch of batteries (Bat.) in order to measure the impedance (Z) diagrams as a function of SoC, SoH and T;

Step E2 adjusts a selected model (RC circuit) (mod.) with the measured impedance diagrams (Z) to determine a set of parameters (para.) that are functions of SoC, SoH and T;

Step E3 calculates the quantities SoC and SoH from a multivariant combination of parameters. A relationship is obtained for the calculation of the SoC and/or a relationship is obtained for the calculation of the SoH (Rel. 1 and Rel. 2);

Step E4 was the selected model and the calculated relationships in a gauge (G) including an instrument (IMI) for measuring the impedance Z by adding an electrical signal to the battery being studied (BatE.), a software portion (LOG) for the adjustment of the selected model (mod.) to the measured impedance Z and then the calculation of the SoC and/or SoH (CALC) from the obtained parameters (para.) and from the relationships calculated previously.

### 1—Measurement of Electrochemical Impedance Diagrams as Function of SoC, SoH

A program of laboratory tests is carried out in order to record the electrochemical impedance diagrams as a function of SoC, SoH and possibly of temperature. In general, for various internal states of at least one second electrochemical system of the same type as the electrochemical system under study,—the property relating to the internal state of the second system is measured (SoC, SoH) and the electrical response of that second electrochemical system is measured at different frequencies.

In one embodiment, for a given type of battery (BatE.), and for a given application for that battery, a battery of the same type is used (Bat.). Next, measurements of electrical responses are made for different states of charge and states of health of that battery. In order to obtain different states of health for that battery, accelerated aging representative of the contemplated application may be carried out. As an example, in the laboratory the battery is subjected to an accelerated aging protocol simulating an on-board application of the hybrid vehicle type or an accelerated aging protocol simulating an application for storing energy of photovoltaic origin connected to the power grid.

The impedance diagrams may be measured by applying a sinusoidal, preferably current, perturbation to a battery by a galvanostat and measuring the sinusoidal voltage induced at the terminals. In another embodiment, the perturbation may be applied as a superposition of a plurality of sinusoidal curves or as white noise (where all frequencies are superimposed in the same signal) rather than in the form of a simple sinusoidal perturbation. This makes possible that several or all of the frequency responses can then be analysed at the same time.

The measurement of the impedance diagrams as a function of SoC may be made over the whole SoC range or over the SoC range corresponding to that used for the application.

The variation in the impedance diagrams with temperature over the temperature range of operation of the application is also measured.

At each state of charge and/or state of aging, the electrical impedance Z of the electrochemical system is measured by application of a current perturbation using a galvanostat.

The complex quantity Z (with a real part ReZ and an imaginary part ImZ) may be represented in the form of a Nyquist diagram where Im(Z) is a function of ReZ with each point corresponding to one frequency. Such a diagram is illustrated in FIG. 3. Responses to rapid phenomena (internal resistance at high frequencies) can then be distinguished from intermediate phenomena, such as the reactions at the electrodes, and from slow phenomena (diffusion of ions in the medium at low frequencies, illustrated by Warburg impedance). These various phenomena are sensitive to SoC and SoH to different extents. Thus, the impedance response changes as a function of the state of charge and aging. The difficulty lies in separating out these effects.

The use of a second battery of the same type as the battery being studied has been described. It is also possible to use a set of batteries of the same type with each of these batteries having a different state of charge and/or state of health.

### 2—Modeling Impedance Diagrams by an Equivalent Electrical Circuit

Nyquist diagrams obtained for all of the states (SoC, SoH and temperature) are modeled, preferably based on an equivalent electrical circuit (arrangement of resistances and capacities in series and/or parallel), knowing that the resistances and capacities will be dependent on the SoC and SoH but not in a simple proportional manner.

FIG. 4 illustrates an example of an equivalent electrical circuit representative of an electrochemical accumulator. R₀ represents the high frequency resistance or series resistance of the element, R₁ represents a charge transfer resistance, Q₁ represents a constant phase element representing electrochemical double layer phenomena, and W represents a Warburg impedance, representing diffusion phenomena.

The equivalent circuit is selected to provide the best model of the impedance of the system for all of the states of a battery, while limiting the number of components and keeping a physical meaning as long as possible.

The selected model (mod.) is adjusted to each impedance diagram of the test program corresponding to each state of SoC, SoH and temperature (T) of the battery, by varying the parameters of the model. Geometric approach modeling is coarser but faster (to obtain the diameter of the semi-circle and the slope of the linear low frequency diffusion portion, for example).

In both cases the descriptive quantities of the models are governed by the SoC and SoH and temperature.

### 3. Determination of a Relationship Between SoC or SoH and the Model Parameters

During this step, a relationship is calibrated between the property (SoC, SoH) and the parameter of the equivalent electrical circuit (model) using a statistical analysis of the values of the property and of the parameter obtained for each internal state.

An equation of the multivariant combination type is determined between the SoC or SoH and the descriptors of the model under consideration.

To this end, a multivariant analysis is carried out between the SoC or SoH on the one hand and the parameters of the model (and possibly the temperature and voltage of the battery) on the other hand. Thus, the SoC and/or SoH are not estimated solely from the change in the values of the different parameters of the equivalent electrical circuits taken independently of each other. In contrast, in accordance with the invention, a law is defined that relies on a combination of all of these parameters, using this multivariant analysis. This means that an optimal multivariant law can be determined, guaranteeing the best estimate of SoC or SoH.

As an example, a Principal Component Analysis type processing of the electrical parameters may be used.

As an example for the electrical model, the following relationship is established between the SoC and the resistances, the Warburg coefficient, etc.:

SOC=a*C₁+b*al₁²+c*W+d*W²+e*R₁+f*L₀.R₀+g*C₁R₁

If proven to be useful, the temperature may be added as a parameter to the model parameters. Similarly, the voltage of the battery may be added to the model parameters as a parameter. This relationship is established as a result of a program of laboratory tests for the selected battery type and the contemplated application, by controlling the parameters T, SoC, SoH and via a mathematical processing, such as PCA of the parameters of the model.

### 4. Estimation of Internal State of Electrochemical System Using the Relationship

The electrical response of the electrochemical system under study is determined for various frequencies. This response is modeled using the equivalent electrical circuit by determining the parameters for which the electrical response of the equivalent electrical circuit is equivalent to the predetermined electrical response. Next, the internal state of the electrochemical system is estimated by calculating the property relating to the internal state of the electrochemical system using the relationship.

In practice, the relationship obtained in the preceding step is used in a sensor (G) having an impedance measuring system (IMI) using any method described in step 1, and a software portion that can:
[calculate the impedance if the measuring system a) does not include it; automatically fit the model selected at step 2 to the measured impedance (LOG); and
the relationships allowing the SoC or SoH determined in step 3 and based on the parameters of the previously adjusted models to be computed, possibly associated with the temperature and the voltage of the battery (CALC).

### EXAMPLE

By way of example, the steps of the method of the invention are applied to two batteries (Li-ion accumulators) with different pairings of materials:
a prototype accumulator using an emerging pairing based on the use of lithium iron phosphate (LiFePO₄) for the positive electrode and lithium titanium oxide (Li₄Ti₅O₁₂) for the negative electrode;
a commercial accumulator with a more conventional pairing based on the use of lithium iron phosphate (LiFePO₄) for the positive electrode and graphite, C₆, for the negative electrode.

### Accelerated Aging Carried Out in the Laboratory

Depending on the case, the batteries were subjected to an accelerated aging protocol simulating on-board application of the hybrid vehicle type, or an accelerated aging protocol simulating an application for storing energy of photovoltaic origin connected to a power grid.

### Impedance Measurement Procedure

In order to validate the method for both SoC and SoH battery diagnostic, a “check-up” test procedure was defined. This procedure was used to characterize the batteries at ambient temperature before and after aging, typically every four weeks.

This test was composed of four consecutive cycles as illustrated in FIG. 2. In this figure, the cycle number is indicated by a figure preceded by the prefix NCy and the curves represent the state of charge.

The first cycle (NCy1) included residual discharge followed by a full charge in order to ensure that the battery was fully charged. The second cycle (NCy2) was a test for evaluating the loss of capacity and thus the state of health of the battery. This test can also be used to adapt the charge-discharge current during the next two cycles. The effects of the state of charge on the impedance measurements were studied by a series of measurements during the last two cycles. The goal of the third cycle (NCy3) is to use potentiostatic type impedance spectroscopy (denoted SIP in the Figure) after a rest period. The goal of the fourth cycle (NCy4) is to measure the impedance without interrupting the current, implying a measurement of the impedance in galvanostatic mode (denoted SIG in the figure) during the charging and discharging phases. The potentiostatic mode, however, is necessarily used during the end of the voltage-regulated charge.

### Impedances and Adjustments

The impedances obtained for various degrees of aging can be represented on the same Nyquist diagram (example FIG. 3) in order to observe the different effects of aging on the total impedance of the battery. FIG. 3 illustrates a comparison between the impedances obtained for several aging states representative of a VEH application at a state of charge of 20% for a Li₄Ti₅O₁₂/LiFePO₄ type battery. VI: initial state; V2: after 2 weeks aging; V3: after 4 weeks; V4: after 6 weeks; V5: after 8 weeks.

Remarkably, it is observed that the impedances are not superimposed. Instead, the impedances of the aged battery produce a semi-circle with a larger radius. These differences are quantified, in accordance with the invention, by adjusting the impedances to an electrical model of the type R0+R1/Q1+W (FIG. 4), wherein the quality of the adjustment can be tested on a Nyquist or Bode diagram (FIG. 5). FIG. 5 shows an example of adjusting the model for impedance between 65 kHz and 0.1 Hz on a Li₄Ti₅O₁₂/LiFePO₄ type battery at 20% SoC in a Nyquist representation, a), and in a Bode representation, b), where the frequency is denoted “freq.”, and using the equivalent circuit model of FIG. 4. (EX): experimental measurement and (MA) is an adjusted model.

Comparing the resistances obtained by adjusting, it is remarkably observed that they increased as a function of aging. In this example, this property is identical irrespective of the temperature at which the impedance was measured. Thus, the influence of aging of the battery on the values of the components of the electrical circuit has been demonstrated and can be used to measure the state of health (SoH) of the battery.

The above impedances were obtained using successive sinusoidal signals with different frequencies. The impedances could be obtained in different ways, such as by superimposing white noise on the charge/discharge signals of the batteries. FIG. 6 presents an impedance measured by the conventional route (sinusoidal signals (SS)) as well as an impedance measured by white noise (BB). Remarkably, a much higher number of points is obtained using white noise, which means that the adjustment can be more precise.

### Determination of State of Health (SoH) of Batteries

These tests were carried out on a Li₄Ti₅O₁₂/LiFePO₄ prototype. The experimental protocol was based on aging of the hybrid vehicle type at 50° C. with check-up periods at 25° C. during which a capacity test was carried out as well as several impedance tests (FIG. 2).

The total capacities of the prototype were known for each step of the check-up procedure.

In accordance with the invention, the impedances were adjusted with a non-linear model using simple electrical elements, such as resistances, capacitors (or constant phase elements, CPE) and Warburg elements (example, FIG. 4). During these experiments, impedance measurements were also carried out during the aging periods.

Twenty-nine impedance measurements are carried out at different states of charge for the battery and at five different states of health. In addition, for each of these measurements, five factors allowed adjustment with respect to a simple equivalent electrical circuit model using R0 (series resistance), R1 (charge transfer resistance), C1 (C1, the quantity Q1 of the CPE), al1 exponents of the CPE and W (Warburg impedance).

After statistical processing of these factors (multi-factorial linear regression), the relationship that was retained was:

SOH=a+b*R₁+c*R₁²+d*R₁³+e*al₁+f*W+g*R₁+h*W²

with R₁, al1 and W representing the adjusted electrical impedance parameters.

The change in the estimated capacities during aging using this relationship was compared with the known capacities of the prototype of FIG. 7.

FIG. 7 represents: in the top graph a), the capacity (Qcalc) estimated from the SoH estimation relationship, is along the ordinate, and the measured capacity of the battery (Q) is along the abscissa. The straight line corresponds to a linear regression. On the bottom graph b), the residuals (ΔQcalc) representing the difference between the capacity calculated from the impedance diagrams are up the ordinate and the capacity of the measured battery (Q) is along the abscissa.

Statistically, the points on graph a) must be close to a straight line of the type y=x in order to verify the reliability of the model. Regarding the residuals, they should have a random dispersion (as is the case here). A non-random dispersion illustrates that the relationship is not adequate.

The change in the residuals representing the difference between the calculated and actual values shows that the estimation is operating correctly. In addition, the correlation coefficient R², which indicates the variance explained by the model, is equal to 0.9999 (if R²=0, there is no correlation, if R²=1, there is complete correlation). The standard error due to the model is 0.25%, which is a very low value, and indicates the accuracy of the model. The variance analyses also indicate that the adjustment factors are all representative of the model. The Kolmogorov-Smirnov test was also carried out. This test can verify that the values calculated by the model and the measured values follow the same law. This test provided a value for P of 0.95 (if P=0, the law is different; if P=1, the law is identical), which is very good for a model. Thus, in the light of the statistical tests that were carried out, the model obtained is valid.

### Validation on Impedances Measured During Aging

Identical impedance measurements during check-up phases (FIG. 2) were carried out during the aging periods and so it was possible to apply the model previously determined to the values for the parameters adjusted to these impedances. It should be pointed out that the aging impedances were measured at 50° C. and not at 25° C., as was the case for the check-up phases, and thus there was a skew in the measurement since the impedance of a battery depends on its temperature.

FIG. 8 presents the capacities (Q) determined by the two methods as a function of the time (t) in hours: cycling during check-up at 20° C. (CK) and impedances at 50° C. measured during aging (VI). It shows a strong similarity between the two types of results as a function of time. The skew arising from the temperature difference was regular and gave values for the estimated capacity that were always higher than the measured capacity values. This result makes sense, as the capacity of a battery always increases with temperature. The SoH (represented by the capacity) during aging can be estimated by the method applied to the impedance diagrams measured during aging, despite the difference in temperature. In fact, in the example used, the temperature parameter was not studied. Integration of this parameter would mean that the precision of the estimation could be improved.

### Determination of State of Charge (SoC) of Batteries

The experimental protocol used a fully charged commercial lithium-ion battery of the graphite/lithium iron phosphate type with a capacity of 2.3 Ah with discharging in steps of 5% state of charge. For each state of charge, the battery was rested to stabilize it, then an impedance measurement was carried out in galvanostatic mode. The data processing was analogous to that applied to determine the state of health.

After statistical processing, the relationship that was retained was:

SOC=a*C₁+b*al₁²+c*W+d*W²+e*R₁+f*L₀.R₀+g*C₁R₁

where R0, R1, C1, al1, L0 and W represent the electrical impedance parameters adjusted as indicated above (Ro is the resistance of the electrolyte, R1 the transfer resistance, C1 the quantity Q1 of the CPE, al1 is the exponent of the CPE, L0 is the high frequency inductance and W is the Warburg impedance).

The change in SoC estimated using this relationship was compared with the known SoC of the battery.

FIG. 9 represents: on the top graph a), the SoC (SoC calc) estimated from the SoC estimation relationship is up the ordinate and the measured SoC of the battery (SoC) is along the abscissa. The straight line corresponds to a linear regression; on the bottom graph b), the residuals (ΔSoC calc) representing the difference between the value calculated from the impedance diagrams is up the ordinate, and along the abscissa is the measured state of charge of the battery (SoC).

The change in the residuals shows that, statistically, the model functions. In addition, the correlation coefficient R², which illustrates the variance explained by the model, was equal to 0.997 (if R²=0, there is no correlation, if R²=1, there is complete correlation). The standard error due to the model is 4% which is very low (4% uncertainty over the SoC of a battery) and indicates the precision of the model. The variance analyses also indicate that the adjustment factors are all representative of the model. The Kolmogorov-Smirnov test was also carried out. This test can verify that the values calculated by the model and the measured values follow the same law. This test provided a value for P of 1 (if P=0, the law is different; if P=1, the law is identical), which is very good for a model. Thus, in the light of the statistical tests that were carried out, the model obtained is valid.

1-14. (canceled)

15. A method for estimating an internal state of a first electrochemical system for storage of electrical energy in which at least one property relating to the internal state of the first electrochemical system is estimated from an electrical measurement obtained from impedance spectroscopy, comprising:
measuring the at least one property relating to internal states of at least one second electrochemical system of a type identical to the first electrochemical system and performing an electrical measurement of the at least one property of the second electrochemical system at multiple frequencies using impedance spectroscopy;
defining an equivalent electrical circuit comprising at least one parameter for modeling electrical responses of the second electrochemical system;
calibrating a relationship between the at least one property and the at least one parameter by performing a statistical analysis of values of the at least one property and values of the at least one parameter;
determining an electrical response of the first electrochemical system at multiple frequencies by determining the at least one parameter such that an electrical response of the equivalent electrical circuit is equivalent to the electrical response of the first electrochemical system; and
estimating the internal state of the first electrochemical system by calculating the at least one property by use of the relationship.

16. A method according to claim 15, wherein:
the internal states of the at least one second electromechanical system are obtained from an accelerated aging of the second electrochemical system for storage of electrical energy of a type identical to the first electrochemical system.

17. A method according to claim 15, wherein:
the internal states are obtained from selection of a set of second electrochemical systems of a type identical to the first electrochemical system with the systems of the set having different internal states.

18. A method according to claim 15, wherein:
at least one of a state of charge (SoC) and a state of health (SoH) of the first electrochemical system is calculated.

19. A method according to claim 16, wherein:
at least one of a state of charge (SoC) and a state of health (SoH) of the first electrochemical system is calculated.

20. A method according to claim 17, wherein:
at least one of a state of charge (SoC) and a state of health (SoH) of the first electrochemical system is calculated.

21. A method according to claim 15, wherein:
the equivalent electrical circuit is defined by parameters selected from resistance, capacitance, temperature or any combination of the parameters.

22. A method according to claim 16, wherein:
the equivalent electrical circuit is defined by parameters selected from resistance, capacitance, temperature or any combination of the parameters.

23. A method according to claim 17, wherein:
the equivalent electrical circuit is defined by parameters selected from resistance, capacitance, temperature or any combination of the parameters.

24. A method according to claim 18, wherein:
the equivalent electrical circuit is defined by parameters selected from resistance, capacitance, temperature or any combination of the parameters.

25. A method according to claim 15, wherein:
an electrical response of the first electrochemical system at the multiple frequencies is determined by measuring diagrams of electrical impedance with the electrical impedance being obtained by adding an electrical current to current passing through the first electrochemical system.

26. A method according to claim 16, wherein:
an electrical response of the first electrochemical system at the multiple frequencies is determined by measuring diagrams of electrical impedance with the electrical impedance being obtained by adding an electrical current to current passing through the first electrochemical system.

27. A method according to claim 17, wherein:
an electrical response of the first electrochemical system at the multiple frequencies is determined by measuring diagrams of electrical impedance with the electrical impedance being obtained by adding an electrical current to current passing through the first electrochemical system.

28. A method according to claim 18, wherein:
an electrical response of the first electrochemical system at the multiple frequencies is determined by measuring diagrams of electrical impedance with the electrical impedance being obtained by adding an electrical current to current passing through the first electrochemical system.

29. A method according to claim 21, wherein:
an electrical response of the first electrochemical system at the multiple frequencies is determined by measuring diagrams of electrical impedance with the electrical impedance being obtained by adding an electrical current to current passing through the first electrochemical system.

30. A method according to claim 25, wherein:
the diagrams of electrical impedance are measured by applying a sinusoidal current to the first electrochemical system and measuring a sinusoidal voltage induced at terminals of the first electrochemical system.

31. A method according to claim 26, wherein:
the diagrams of electrical impedance are measured by applying a sinusoidal current to the first electrochemical system and measuring a sinusoidal voltage induced at terminals of the first electrochemical system.

32. A method according to claim 27, wherein:
the diagrams of electrical impedance are measured by applying a sinusoidal current to the first electrochemical system and measuring a sinusoidal voltage induced at terminals of the first electrochemical system.

33. A method according to claim 28, wherein:
the diagrams of electrical impedance are measured by applying a sinusoidal current to the first electrochemical system and measuring a sinusoidal voltage induced at terminals of the first electrochemical system.

34. A method according to claim 29, wherein:
the diagrams of electrical impedance are measured by applying a sinusoidal current to the first electrochemical system and measuring a sinusoidal voltage induced at terminals of the first electrochemical system.

35. A method according to claim 25, wherein:
the diagrams of electrical impedance are measured by applying sinusoidal current or white noise to the first electrochemical system and measuring a sinusoidal voltage induced at terminals of the first electrochemical system.

36. A method according to claim 26, wherein:
the diagrams of electrical impedance are measured by applying sinusoidal current or white noise to the first electrochemical system and measuring a sinusoidal voltage induced at terminals of the first electrochemical system.

37. A method according to claim 27, wherein:
the diagrams of electrical impedance are measured by applying sinusoidal current or white noise to the first electrochemical system and measuring a sinusoidal voltage induced at terminals of the first electrochemical system.

38. A method according to claim 28, wherein:
the diagrams of electrical impedance are measured by applying sinusoidal current or white noise to the first electrochemical system and measuring a sinusoidal voltage induced at terminals of the first electrochemical system.

39. A method according to claim 29, wherein:
the diagrams of electrical impedance are measured by applying sinusoidal current or white noise to the first electrochemical system and measuring a sinusoidal voltage induced at terminals of the first electrochemical system.

40. A method according to claim 15, comprising:
estimating the internal state of the first electrochemical system while the first electrochemical system is either at rest or operating.

41. A system for estimating an internal state of first electrochemical system for storage of electrical energy, comprising:
a sensor including means for measuring electrical impedance of the first electrochemical system by use of impedance spectroscopy;
a memory for storing a representation of an equivalent electrical circuit of at least one second electrochemical system for storage of electrical energy of a type identical to the first electrochemical system and a relationship between at least one property relating to an internal state of the first electrochemical system and at least one parameter of the equivalent electrical circuit with the relationship being calibrated from measurements of internal states of the at least one second electrochemical system of a type identical to the first electrochemical system;
means for defining parameters of the first equivalent electrical circuit for modeling an electrical response of the first electrochemical system for storage of energy; and
means for calculating the at least one property relating to the internal state of the first electrochemical system using the relationship.

42. A system according to claim 41, wherein the means for measuring the electrical impedance comprises:
a galvanostat for applying at least one sinusoidal current or a white noise to the first electrochemical system; and
means for measuring a sinusoidal voltage induced at terminals of the first electrochemical system.

43. A system according to claim 41, wherein:
the first electrochemical system comprises a battery and a management system for the battery.

44. A system according to claim 42, wherein:
the first electrochemical system comprises a battery and a management system for the battery.

45. A system in accordance with claim 43 comprising:
a vehicle including the battery.

46. A system in accordance with claim 44 comprising:
a vehicle including the battery.

47. A system in accordance with claim 41 comprising:
a photovoltaic system.

48. A system in accordance with claim 42 comprising:
a photovoltaic system.
